(19) United States
(12) Patent Application Publication
(10) Pub. No.: US 2021/0336226 A1
(43) Pub. Date: Oct. 28, 2021

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Shiqi LIU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/626,533

(22) PCT Filed: Nov. 13, 2019
(86) PCT No.: PCT/CN2019/117855

§ 371 Date: Dec. 25, 2019

(30) Foreign Application Priority Data
Oct. 12, 2019 (CN) 201910968813.2

(51) Int. Cl. H01L 51/52; H01L 27/32

(52) U.S. Cl. CPC H01L 51/5275; H01L 51/5253; H01L 27/3244

(57) ABSTRACT

The present disclosure provides a display panel and a display device. The display panel includes a substrate, a light emitting layer on the substrate, a thin film encapsulation layer on the light emitting layer, and a cover plate layer on the thin film encapsulation layer. A surface of at least one film layer of a film layer structure between the substrate and the cover plate layer is convex.

### FIELD OF INVENTION

The present disclosure relates to a technology field of displays, and particularly relates to a display panel and a display device.

### BACKGROUND OF INVENTION

Organic light emitting diode (OLED) displays have many advantages such as light weight, active light emission, fast response speed, wide viewing angles, wide color gamut, high brightness, and low power consumption. They have gradually become the third-generation display technology after LCD displays.

In prior art, for top-emitting OLED display panels, part of the light emitted by a luminous layer will be reflected by the anode, which causes this part of the light to be emitted from the top of the OLED display panel at various angles, thereby making the display panel appear to have brightness differences at different viewing angles, which affects the quality of the product.

Therefore, a display panel is urgently needed to solve the above technical problems.

### SUMMARY OF INVENTION

The present disclosure provides a display panel and a display device to solve the problems that the display panel in prior art has bright differences at different viewing angles.

To solve above problems, the technical solutions provided by the present disclosure are as follows:

The present disclosure provides a display panel, including a substrate, a light emitting layer on the substrate, a thin film encapsulation layer on the light emitting layer, and a cover plate layer on the thin film encapsulation layer; therein, a surface of at least one film layer of a film layer structure between the substrate and the cover plate layer is convex.

In the display panel of the present disclosure, the display panel includes a first convex surface; a film layer located on a side of the first convex surface adjacent to a light emitter is a first film layer; a film layer located on a side of the first convex surface away from the light emitter is a second film layer; and a refractive index of the first film layer is less than a refractive index of the second film layer.

In the display panel of the present disclosure, a light emitting direction of the display panel is from the light emitting layer to the cover plate layer; the light emitting layer includes an anode layer on the substrate, a luminous layer on the anode layer, and a cathode layer on the luminous layer; and the first convex surface is a common surface between any two adjacent film layers between the luminous layer and the cover plate layer.

In the display panel of the present disclosure, the thin film encapsulation layer includes at least one inorganic layer and at least one organic layer, the inorganic layer and the organic layer are laminated, and the first convex surface is a common surface between any two adjacent layers of the inorganic layer and the organic layer.

In the display panel of the present disclosure, the thin film encapsulation layer includes a first inorganic layer, a first organic layer on the first inorganic layer, a second organic layer on the first organic layer, and a second inorganic layer on the second organic layer; and the first convex surface is a common surface between the first organic layer and the second organic layer.

In the display panel of the present disclosure, a light emitting direction of the display panel is from the light emitting layer to the substrate; and the first convex surface is a common surface between any two adjacent film layers between a luminous layer and the cover plate layer.

In the display panel of the present disclosure, the display panel further includes a thin film transistor between the substrate and the light emitting layer; the thin film transistor includes a buffer layer on the substrate, a gate insulating layer on the buffer layer, an interlayer dielectric layer on the gate insulating layer, and a planarization layer on the interlayer dielectric layer; and the first convex surface is a common surface between any two adjacent layers of the substrate, the buffer layer, the gate insulating layer, the interlayer dielectric layer, the planarization layer, and an anode layer.

In the display panel of the present disclosure, the light emitting layer includes at least one light emitting unit; the light emitting unit is arranged opposite to the first convex surface; and an orthographic projection of the light emitting unit on the substrate is located within an orthographic projection of the first convex surface on the substrate.

In the display panel of the present disclosure, the display panel further includes a second convex surface; the second convex surface is arranged opposite to the light emitting unit; the second convex surface is located on a side of the first convex surface away from the light emitter; and an orthographic projection of the second convex surface on the substrate is located within the orthographic projection of the first convex surface on the substrate.

The present disclosure also provides a display device including a display panel, the display panel includes a substrate, a light emitting layer on the substrate, a thin film encapsulation layer on the light emitting layer, and a cover plate layer on the thin film encapsulation layer; therein, a surface of at least one film layer of a film layer structure between the substrate and the cover plate layer is convex.

In the display device of the present disclosure, the display panel includes a first convex surface; a film layer located on a side of the first convex surface adjacent to the light emitter is a first film layer; a film layer located on a side of the first convex surface away from the light emitter is a second film layer; and a refractive index of the first film layer is less than a refractive index of the second film layer.

In the display device of the present disclosure, a light emitting direction of the display panel is from the light emitting layer to the cover plate layer; the light emitting layer includes an anode layer on the substrate, a luminous layer on the anode layer, and a cathode layer on the luminous layer; and the first convex surface is a common surface between any two adjacent film layers between the luminous layer and the cover plate layer.

In the display device of the present disclosure, the thin film encapsulation layer includes at least one inorganic layer and at least one organic layer, the inorganic layer and the organic layer are laminated, and the first convex surface is a common surface between any two adjacent layers of the inorganic layer and the organic layer.

In the display device of the present disclosure, the thin film encapsulation layer includes a first inorganic layer, a first organic layer on the first inorganic layer, a second organic layer on the first organic layer, and a second inorganic layer on the second organic layer; and the first convex surface is a common surface between the first organic layer and the second organic layer.

In the display device of the present disclosure, a light emitting direction of the display panel is from the light emitting layer to the substrate; and the first convex surface is a common surface between any two adjacent film layers between a luminous layer and the cover plate layer.

In the display device of the present disclosure, the display panel further includes a thin film transistor between the substrate and the light emitting layer; the thin film transistor includes a buffer layer on the substrate, a gate insulating layer on the buffer layer, an interlayer dielectric layer on the gate insulating layer, and a planarization layer on the interlayer dielectric layer; and the first convex surface is a common surface between any two adjacent layers of the substrate, the buffer layer, the gate insulating layer, the interlayer dielectric layer, the planarization layer, and an anode layer.

In the display device of the present disclosure, the light emitting layer includes at least one light emitting unit; the light emitting unit is arranged opposite to the first convex surface; and an orthographic projection of the light emitting unit on the substrate is located within an orthographic projection of the first convex surface on the substrate.

In the display device of the present disclosure, the display panel further includes a second convex surface; the second convex surface is arranged opposite to the light emitting unit; the second convex surface is located on a side of the first convex surface away from the light emitter; and an orthographic projection of the first convex surface on the substrate is located within the orthographic projection of the second convex surface on the substrate.

Beneficial effects: the present disclosure provides at least one convex surface in the light emitting direction of the display panel, and the emitted light exits the display panel at a predetermined angle through the convex surface, so that the display panel has the same brightness at different viewing angles, thereby improving product quality.

### DESCRIPTION OF DRAWINGS

In order to more clearly illustrate the technical solutions in the embodiments or the prior art, the drawings to be used in the descriptions of the embodiments or the prior art will be briefly described below. Obviously, the drawings in the following description are merely embodiments of the present disclosure. For those of ordinary skill in the art, other drawings may be obtained from the drawings without any creative work.

FIG. 1 is a first schematic view of a display panel of the present disclosure.

FIG. 2 is a second schematic view of a display panel of the present disclosure.

FIG. 3 is a third schematic view of a display panel of the present disclosure.

FIG. 4 is a fourth schematic view of a display panel of the present disclosure.

FIG. 5 is a fifth schematic view of a display panel of the present disclosure.

FIG. 6 is a sixth schematic view of a display panel of the present disclosure.

FIG. 7 is a seventh schematic view of a display panel of the present disclosure.

FIG. 8 is an eighth schematic view of a display panel of the present disclosure.

### DETAILED DESCRIPTION OF EMBODIMENTS

The following description of the various embodiments refers to the accompanying drawings, and is provided to illustrate the specific embodiments of the invention. Orientational relationships represented by directional terms mentioned in the present disclosure, such as “up”, “down”, “front”, “rear”, “left”, “right”, “inner”, “outer”, or “lateral”, etc. are orientational relationships based on illustration of the drawings. So, the orientational relationships used are for describing and understanding of the present disclosure, rather than limiting the present disclosure. In the figures, structurally similar elements are denoted by the same reference numerals.

In the OLED display panel of the prior art, since part of the light emitted from a luminous layer exits the display panel through the reflection of the cathode layer or the anode layer, the part of the light is emitted from the OLED display panel under various angles, which causing brightness difference of the display panel under different viewing angles, thereby affecting the quality of the product. Therefore, the present application proposes a display panel to solve the above technical problems.

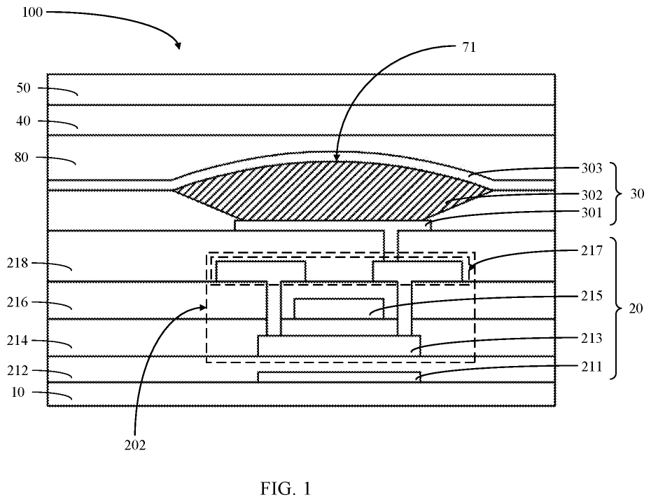

Referring to FIGS. 1-8, the display panel 100 includes a substrate 10, a thin film transistor layer 20 on the substrate 10, a light emitting layer 30 on the thin film transistor layer 20, a thin film encapsulation layer 40 on the light emitting layer 30, and a cover plate layer 50 on the thin film encapsulation layer 40.

Therein, a surface of at least one film layer of a film layer structure between the substrate 10 and the cover plate layer 50 is convex towards a light emitting direction of the display panel 100.

In the display panel 100 of the present disclosure, the display panel 100 includes at least one first convex surface 71.

A film layer located on a side of the first convex surface 71 adjacent to a light emitter is a first film layer.

A film layer located on a side of the first convex surface 71 away from the light emitter is a second film layer.

Therein, a refractive index of the first film layer is less than a refractive index of the second film layer.

Referring to FIG. 1, it is a first schematic view of the display panel 100 of the present disclosure.

In this embodiment, the substrate 10 may be one of a glass substrate, a quartz substrate, or a resin substrate, etc.

In this embodiment, the substrate 10 may be a flexible substrate. Materials of the flexible substrate may include polyimide (PI). The substrate 10 may be provided with a double-layered polyimide layer to further increase the flexibility of the substrate 10.

The thin film transistor layer 20 includes at least one thin film transistor 21. The thin film transistor 21 may be one of an etch stop type, a back channel etch type, or a top gird thin film transistor 21 type, etc., and there is no specific limitation.

For example, the thin film transistor 21 of a top gird thin film transistor type may include a light shielding layer 211, a buffer layer 212, an active layer 213, a gate insulating layer 214, a gate electrode layer 215, an interlayer dielectric layer 216, a source and drain electrode layer 217, and a planarization layer 218.

In this embodiment, the light shielding layer 211 is on the substrate 10, and is covered by the buffer layer 212. An orthographic projection of the thin film transistor 21 on the light shielding layer 211 is located within the light shielding layer 211.

The buffer layer 212 is mainly used for buffering a pressure between the membrane structures, and may also have a function of blocking water and oxygen. In this embodiment, a material of the buffer layer 212 may include one or more combinations of silicon nitride or silicon oxide.

The active layer 213 is on the buffer layer 212. In this embodiment, a material of the active layer 213 may be low temperature polysilicon (LTPS) or indium gallium zinc oxide (IGZO), and it is not limited in the present disclosure.

The gate insulating layer 214, the gate electrode layer 215, the interlayer dielectric layer 216, the source and drain electrode layer 217, and the planarization layer 218 are usually provided, which are not described in the present disclosure.

The light emitting layer 30 includes an anode layer 301 on the planarization layer 218, a luminous layer 302 on the anode layer 301, and a cathode layer 302 on the luminous layer 302.

The display panels 100 are divided into top-emitting display panels and bottom-emitting display panels according to different light-emitting directions.

The present disclosure uses a top-emitting display panel as an example for description.

Referring to FIG. 1, the anode layer 301 of the present disclosure may be composed of a non-transparent material, and light emitted by the luminous layer 302 is reflected by the anode layer 301, and then is emitted from the cover plate layer 50.

In this embodiment, the first convex surface 71 is a common surface between the luminous layer 302 and the cathode layer 303. The luminous layer 302 is formed into a pattern as shown in FIG. 1 through a predetermined process. The first film layer in this embodiment is the luminous layer 302.

The cathode layer 303 may not be able to form a flat cathode layer 303 due to process limitations. A visual improvement layer 80 may be formed on a surface of the cathode layer 303 to adjust the light output angle. In addition, since the cathode layer 303 is made of a conductive material, and a refractive index of the conductive material is generally greater than that of an organic material, the cathode layer 303 cannot be provided as the second film layer.

In this embodiment, a refractive index of the visual improvement layer 80 is smaller than that of the cathode layer 303.

Similarly, the visual improvement layer 80 can also be replaced by an encapsulation layer or a film structure, which is not specifically limited in the present disclosure.

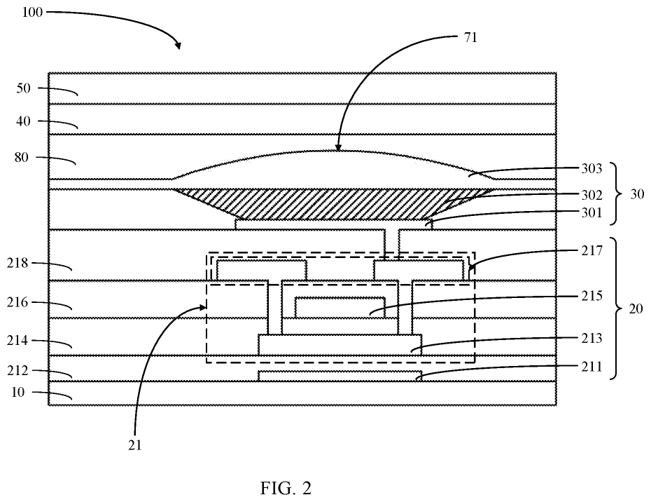

Referring to FIG. 2, it is a second schematic view of the display panel 100 of the present disclosure.

This embodiment is the same as or similar to the embodiment shown in FIG. 1, except that:

The first convex surface 71 is a common surface between the cathode layer 303 and an inorganic layer or an organic layer on the cathode layer 303.

In this embodiment, the first film layer is the cathode layer 303. The cathode layer 303 is patterned to form a raised pattern as shown in FIG. 2 on any one light emitting unit.

The second film layer may be the visual improvement layer 80 shown in FIG. 2. Since a refractive index of the first film layer need to be less than a refractive index of the second film layer. Materials of the visual improvement layer 80 and the cathode layer 303 should be selected to meet the above refractive index relationship.

The thin film encapsulation layer 40 may include at least one inorganic layer and at least one organic layer, and the inorganic layer and the organic layer are laminated. The first convex surface 71 can be a common surface between any two adjacent layers of the inorganic layer and the organic layer.

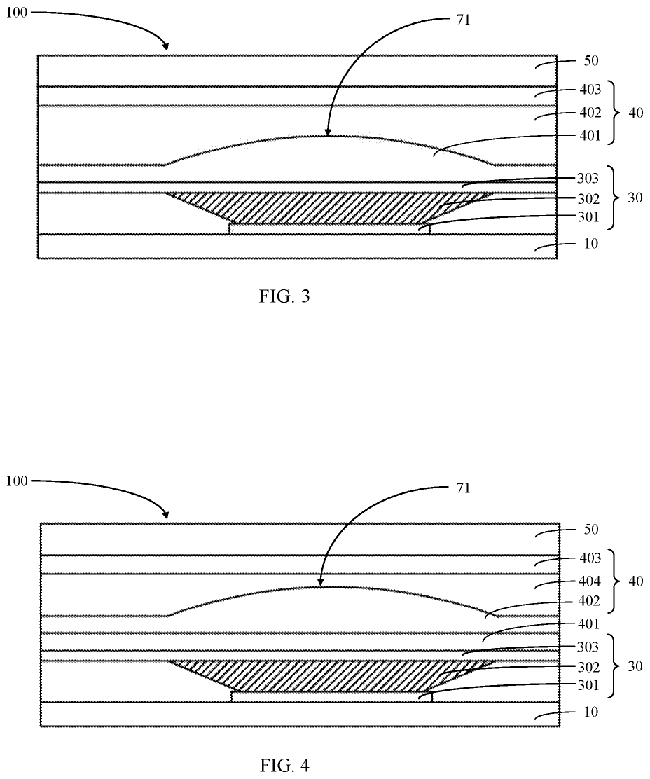

Referring to FIG. 3, it is a third schematic view of the display panel 100 of the present disclosure.

The thin film encapsulation layer 40 includes a first inorganic layer 401 on the cathode layer 303, a first organic layer 402 on the first inorganic layer 401, and a second inorganic layer 403 on the first organic layer 402.

In this embodiment, the first convex surface 71 may be a common surface between the first inorganic layer 401 and the first organic layer 402. The first film layer may be the first inorganic layer 401, and the second film layer may be the first organic layer 402. Since the first organic layer 402 is made of specific fluid organic materials, even if bumps are provided in the first inorganic layer 401, a surface of the first organic layer 402 is flat.

In this embodiment, a refractive index of the first inorganic layer 401 is less than a refractive index of the first organic layer 402.

Since a thickness of an inorganic layer is greatly greater than a thickness of an organic layer, the first convex surface 71 is unsuitable to be a common surface between the first organic layer 402 and the second inorganic layer 403. However, forming the visual improvement layer 80 on a surface of the second inorganic layer 403 can achieve the same visual effect.

Referring to FIG. 4, it is a fourth schematic view of the display panel 100 of the present disclosure.

This embodiment is the same as or similar to the embodiment shown in FIG. 3, except that:

The thin film encapsulation layer 40 includes a first inorganic layer 401 on the cathode layer 303, a first organic layer 402 on the first inorganic layer 401, a second organic layer 404 on the first organic layer 402, and a second inorganic layer 403 on the second organic layer 404.

In this embodiment, the first convex surface 71 may be a common surface between the first organic layer 402 and the second organic layer 404.

This embodiment uses a predetermined process to form a convex structure as shown in FIG. 4 by using two organic layers having different refractive indexes. The first film layer is the first organic layer 402, and the second film layer is the second organic layer 404.

In this embodiment, a refractive index of the first organic layer 402 is less than a refractive index of the second organic layer 404.

In this embodiment, the second organic layer 404 may also be replaced by the visual improvement layer 80.

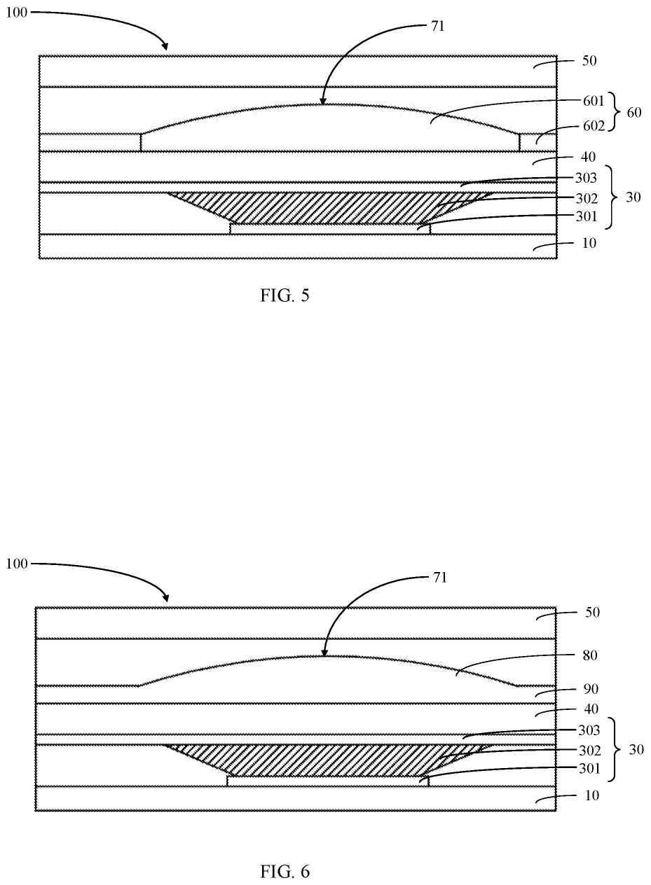

Referring to FIG. 5, it is a fifth schematic view of the display panel 100 of the present disclosure.

The display panel 100 may further include a color filter layer 60.

Regarding to different light emitting directions, the color filter layer 60 may be located between the substrate 10 and the luminous layer 302, or between the luminous layer 302 and the cover plate layer. In this embodiment, the color filter layer 60 is located on the thin film encapsulation layer 40.

The color filter layer 60 includes a plurality of color resistance units and light shielding units 602 on both sides of the color resistance unit 601. A side of the color resistance unit 601 away from the luminous layer 302 is convex.

In this embodiment, the first convex surface 71 may be a common surface between the color resistance unit 601 and an inorganic layer or an organic layer on the color resistance unit 601.

In this embodiment, a refractive index of the color resistance unit 601 is smaller than that of the inorganic layer or that of the organic layer on the color resistance unit 601.

Similarly, the inorganic layer or the organic layer on the color resistance unit 601 may also be replaced by the visual improvement layer 80.

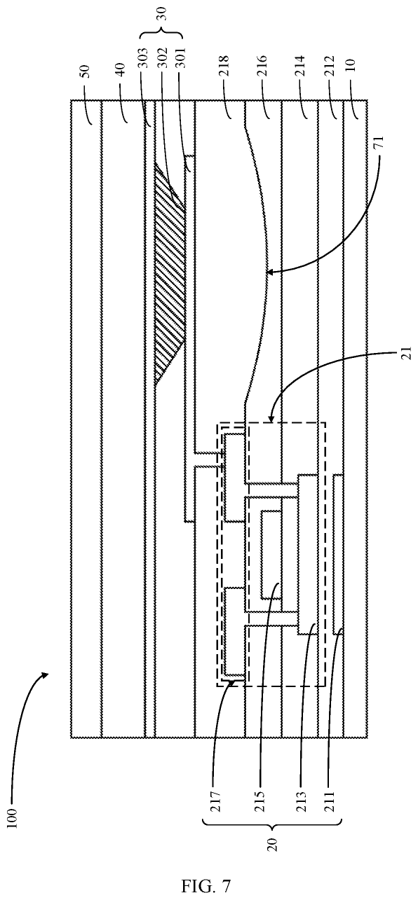

Referring to FIG. 6, it is a sixth schematic view of the display panel 100 of the present disclosure.

The display panel 100 may further includes a packing layer 90 between the thin film encapsulation layer 40 and the cover plate layer 50, and a visual improvement layer 80 on the packing layer 90.

In this embodiment, the first convex surface 71 is a common surface between the packing layer 90 and the visual improvement layer 80.

In this embodiment, a refractive index of the packing layer 90 is smaller than that of the visual improvement layer 80.

The following uses a bottom-emitting display panel as an example for description.

In a bottom-emitting display panel, the light emitting direction of the display panel 100 is from the light emitting layer 30 to the substrate 10. Light emitted from the luminous layer 302 is reflected by the cathode layer 303, passes through the anode layer 301, and then exits from the substrate 10.

In the bottom-emitting display panel 100, the first convex surface 71 is a common surface between any two adjacent film layers between the luminous layer 302 and the substrate 10.

Referring to FIG. 7, it is a seventh schematic view of the display panel 100 of the present disclosure.

Since the thin film transistor 21 is non-translucent, the positions of the thin film transistor 21 in the bottom-emitting display panel 100 and the top-emitting display panel 100 are different, which is not described in detail in the present disclosure.

The present disclosure uses one of the embodiments as an example for description.

In this embodiment, the first convex surface 71 is a common surface between the interlayer dielectric layer 216 and the planarization layer 218. The first film layer is the planarization layer 218, and the second film layer is the interlayer dielectric layer 216.

In this embodiment, a refractive index of the planarization layer 218 is less than a refractive index of the interlayer dielectric layer 216.

In an embodiment, the first convex surface 71 may also be a common surface between any two adjacent film layers of the substrate 10, the buffer layer 212, the gate insulating layer 214, the interlayer dielectric layer 216, the planarization layer 218, and the anode layer 301.

The first convex surface 71 of the present disclosure is named according to the light emitting direction of the display panel 100. Hence, even though the first convex surface 71 shown in FIG. 7 is a concave surface, the first convex surface 71 is convex according to the light emitting direction of the display panel 100.

In the above FIG. 1 to FIG. 7, the luminous layer 302 includes a plurality of light emitting units. Each light emitting unit corresponds to one of the first convex surfaces 71.

In the above embodiment, an orthographic projection of the light emitting unit on the substrate 10 is located within an orthographic projection of the first convex surface 71 on the substrate 10.

In this embodiment, an area of the first convex surface 71 is generally greater than an area of the light emitting unit.

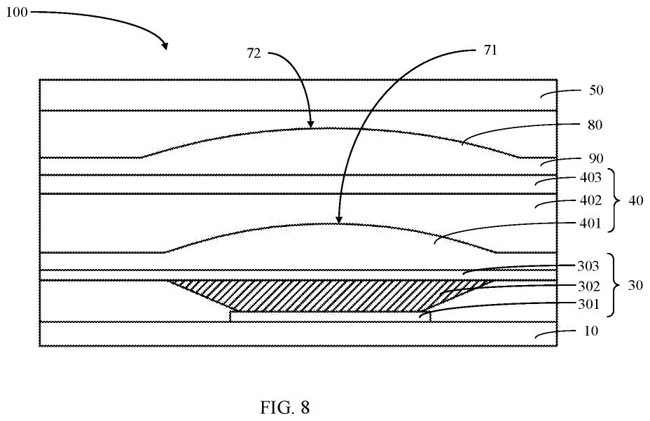

Referring to FIG. 8, it is an eighth schematic view of the display panel 100 of the present disclosure.

This embodiment is the same as or similar to the embodiment shown in FIG. 3, except that:

The display panel 100 further includes at least one second convex surface 72. The second convex surface 72 corresponds to one of the light emitting units. The second convex surface 72 is located on a side of the first convex surface 71 away from the light emitter.

In this embodiment, the second convex surface 72 is located on the thin film encapsulation layer 40.

The embodiment shown in FIG. 8 can be regarded as a combination of the embodiments shown in FIG. 3 and FIG. 6.

Since the second convex surface 72 is located on the first convex surface 71, an area of the second convex surface 72 generally needs to be greater than an area of the first convex surface 71 to ensure adjustments of different viewing angles of the display panel 100.

In this embodiment, an orthographic projection of the first convex surface 71 on the substrate 10 is within an orthographic projection of the second convex surface 72 on the substrate 10.

Based on FIG. 8, the second convex surface 72 may be a combination of any two embodiments shown in FIG. 1 to FIG. 6, which is not specifically limited in the present disclosure.

Based on FIG. 8, the display panel 100 further includes a third convex surface located on a side of the second convex surface 72 away from the light emitter, and more convex surfaces, which are not specifically limited in the present disclosure.

In the present disclosure, that the display panel has the same brightness at different viewing angles is mainly based on a large refraction angle generated when the light is emitted from a light-dense medium to a light-sparse medium. A radian of the first convex surface can be adjusted according to the refractive index and thickness of the first and second film layer, so that the display panel can meet the needs of users.

The present disclosure also provides a display device. Therein, the display device includes the above display panel. A rationale of the display device is the same as or similar to the display panel described above, which is not described in the present disclosure.

The display panel provided in the present disclosure includes the substrate, the light emitting layer on the substrate, the thin film encapsulation layer on the light emitting layer, and a cover plate layer on the thin film encapsulation layer. A surface of at least one film layer of a film layer structure between the substrate and the cover plate layer is convex. In the present disclosure, at least one convex surface is provided in the light emitting direction of the display panel, and the emitted light exits the display panel at a predetermined angle through the convex surface, so that the display panel has the same brightness at different viewing angles, thereby improving product quality.

To sum up, the present disclosure has been disclosed as above in the preferred embodiments. However, the preferred embodiments should not be construed as limitations of the present disclosure. Those skilled in the art can make various modifications without departing from the spirit and scope of the present disclosure. Hence, the scope of the present disclosure should be subject to the scope defined in the claims.

What is claimed is:

1. A display panel, comprising
a substrate;
a light emitting layer on the substrate;
a thin film encapsulation layer on the light emitting layer; and
a cover plate layer on the thin film encapsulation layer;
wherein a surface of at least one film layer of a film layer structure between the substrate and the cover plate layer is convex.

2. The display panel as claimed in claim 1, wherein,
the display panel comprises a first convex surface;
a film layer located on a side of the first convex surface adjacent to a light emitter is a first film layer;
a film layer located on a side of the first convex surface away from the light emitter is a second film layer; and
a refractive index of the first film layer is less than a refractive index of the second film layer.

3. The display panel as claimed in claim 2, wherein,
a light emitting direction of the display panel is from the light emitting layer to the cover plate layer;
the light emitting layer comprises an anode layer on the substrate, a luminous layer on the anode layer, and a cathode layer on the luminous layer; and
the first convex surface is a common surface between any two adjacent film layers between the luminous layer and the cover plate layer.

4. The display panel as claimed in claim 3, wherein, the thin film encapsulation layer comprises at least one inorganic layer and at least one organic layer, the inorganic layer and the organic layer are laminated, and the first convex surface is a common surface between any two adjacent layers of the inorganic layer and the organic layer.

5. The display panel as claimed in claim 3, wherein,
the thin film encapsulation layer comprises a first inorganic layer, a first organic layer on the first inorganic layer, a second organic layer on the first organic layer, and a second inorganic layer on the second organic layer; and
the first convex surface is a common surface between the first organic layer and the second organic layer.

6. The display panel as claimed in claim 2, wherein,
a light emitting direction of the display panel is from the light emitting layer to the substrate; and
the first convex surface is a common surface between any two adjacent film layers between a luminous layer and the cover plate layer.

7. The display panel as claimed in claim 6, wherein, the display panel further comprises a thin film transistor between the substrate and the light emitting layer;
the thin film transistor comprises a buffer layer on the substrate, a gate insulating layer on the buffer layer, an interlayer dielectric layer on the gate insulating layer, and a planarization layer on the interlayer dielectric layer; and
the first convex surface is a common surface between any two adjacent layers of the substrate, the buffer layer, the gate insulating layer, the interlayer dielectric layer, the planarization layer, and an anode layer.

8. The display panel as claimed in claim 2, wherein,
the light emitting layer comprises at least one light emitting unit;
the light emitting unit is arranged opposite to the first convex surface; and
an orthographic projection of the light emitting unit on the substrate is located within an orthographic projection of the first convex surface on the substrate.

9. The display panel as claimed in claim 8, wherein,
the display panel further comprises a second convex surface;
the second convex surface is arranged opposite to the light emitting unit;
the second convex surface is located on a side of the first convex surface away from the light emitter; and
an orthographic projection of the second convex surface on the substrate is located within the orthographic projection of the first convex surface on the substrate.

10. A display device, comprising a display panel, the display panel comprising
a substrate;
a light emitting layer on the substrate;
a thin film encapsulation layer on the light emitting layer; and
a cover plate layer on the thin film encapsulation layer;
wherein a surface of at least one film layer of a film layer structure between the substrate and the cover plate layer is convex.

11. The display device as claimed in claim 10, wherein,
the display panel comprises a first convex surface;
a film layer located on a side of the first convex surface adjacent to the light emitter is a first film layer;
a film layer located on a side of the first convex surface away from the light emitter is a second film layer; and
a refractive index of the first film layer is less than a refractive index of the second film layer.

12. The display device as claimed in claim 11, wherein,
a light emitting direction of the display panel is from the light emitting layer to the cover plate layer;
the light emitting layer comprises an anode layer on the substrate, a luminous layer on the anode layer, and a cathode layer on the luminous layer; and
the first convex surface is a common surface between any two adjacent film layers between the luminous layer and the cover plate layer.

13. The display device as claimed in claim 12, wherein, the thin film encapsulation layer comprises at least one inorganic layer and at least one organic layer, the inorganic layer and the organic layer are laminated, and the first convex surface is a common surface between any two adjacent layers of the inorganic layer and the organic layer.

14. The display device as claimed in claim 12, wherein,
the thin film encapsulation layer comprises a first inorganic layer, a first organic layer on the first inorganic layer, a second organic layer on the first organic layer, and a second inorganic layer on the second organic layer; and
the first convex surface is a common surface between the first organic layer and the second organic layer.

15. The display device as claimed in claim 11, wherein,
a light emitting direction of the display panel is from the light emitting layer to the substrate; and
the first convex surface is a common surface between any two adjacent film layers between a luminous layer and the cover plate layer.

16. The display device as claimed in claim 15, wherein, the display panel further comprises a thin film transistor between the substrate and the light emitting layer;
the thin film transistor comprises a buffer layer on the substrate, a gate insulating layer on the buffer layer, an interlayer dielectric layer on the gate insulating layer, and a planarization layer on the interlayer dielectric layer; and
the first convex surface is a common surface between any two adjacent layers of the substrate, the buffer layer, the gate insulating layer, the interlayer dielectric layer, the planarization layer, and an anode layer.

17. The display device as claimed in claim 11, wherein,
the light emitting layer comprises at least one light emitting unit;
the light emitting unit is arranged opposite to the first convex surface; and
an orthographic projection of the light emitting unit on the substrate is located within an orthographic projection of the first convex surface on the substrate.

18. The display device as claimed in claim 17, wherein,
the display panel further comprises a second convex surface;
the second convex surface is arranged opposite to the light emitting unit;
the second convex surface is located on a side of the first convex surface away from the light emitter; and
an orthographic projection of the first convex surface on the substrate is located within the orthographic projection of the second convex surface on the substrate.
